(19) United States
(12) Patent Application Publication
(10) Pub. No.: US 2026/0252765 A1
(43) Pub. Date: Aug. 27, 2026

(54) DOMAIN-SPECIFIC COMPUTER ARCHITECTURE FOR PLASMA SIMULATIONS

(71) Applicant: Tokyo Electron Limited, Tokyo (JP)

(72) Inventor: Mirko Vukovic, Albany, NY (US)

(21) Appl. No.: 19/455,325

(22) Filed: Jan. 21, 2026

Related U.S. Application Data
(60) Provisional application No. 63/761,789, filed on Feb. 21, 2025.

(51) Int. Cl. G06F 30/27

(52) U.S. Cl. CPC G06F 30/27

(57) ABSTRACT

A method of designing domain-specific computer architecture (DSA) for plasma simulation includes providing a training set to an artificial intelligence (AI) model, the training set including plasma processing parameters and hardware parameters used for the plasma processing parameters, and training the AI model using the training set to form a trained AI model, the trained AI model configured to output hardware parameters based on a plasma process parametrization. The method further includes inputting a desired plasma process parametrization to the trained AI model, the trained AI model outputting hardware parameters, and designing, using the hardware parameters, the DSA for performing plasma simulations of the desired plasma process parametrization.

### CROSS-REFERENCE TO RELATED APPLICATIONS

This application claims the benefit of U.S. Provisional Application No. 63/761,789, filed on February 21, 2025, which application is hereby incorporated herein by reference.

### TECHNICAL FIELD

The present invention relates generally to the field of plasma simulations in semiconductor manufacturing, and, in particular embodiments, to systems and methods for accelerating and simplifying plasma simulations using domain-specific computer architectures and artificial intelligence interfaces.

### BACKGROUND

Artificial intelligence (AI) has been gradually gaining traction in the field of plasma simulations for semiconductor manufacturing. In recent years, researchers and engineers have explored various AI techniques to enhance the efficiency and accuracy of plasma simulations. These efforts have used machine learning algorithms for parameter optimization, neural networks for predicting plasma behavior, and expert systems for interpreting simulation results. However, the integration of AI into plasma simulations has been limited by factors such as the complexity of plasma physics, the high dimensionality of simulation data, and the extensive domain expertise. Additionally, the size of computational resources of both AI algorithms and plasma simulations have posed challenges for widespread adoption. Despite these obstacles, the potential benefits of AI in reducing simulation times, improving accuracy, and making simulations more accessible to non-experts have continued to drive research and development in this area.

### SUMMARY

In accordance with an embodiment of this disclosure, a method of designing domain-specific computer architecture (DSA) for plasma simulation includes providing a training set to an artificial intelligence (AI) model, the training set including plasma processing parameters and hardware parameters used for the plasma processing parameters, and training the AI model using the training set to form a trained AI model, the trained AI model configured to output hardware parameters based on a plasma process parametrization. The method further includes inputting a desired plasma process parametrization to the trained AI model, the trained AI model outputting hardware parameters, and designing, using the hardware parameters, the DSA for performing plasma simulations of the desired plasma process parametrization.

In accordance with another embodiment of this disclosure, a method of training an artificial intelligence (AI) model for optimally allocating resources of a domain-specific computer architecture (DSA) includes providing a training set to the AI model, the training set including plasma processing parameters and resource allocations of the DSA used for the plasma processing parameters, the DSA including specialized physics solvers with dedicated memory and arithmetic units and an inter-solver communication circuit for coordinating data exchange between the specialized physics solvers, the resource allocations including information on how the inter-solver communication circuit coordinated data exchange between the specialized physics solvers and how each dedicated memory was allocated. The method further includes training the AI model using the training set to form a trained AI model, the trained AI model configured to output resource allocation information based on the DSA and the plasma processing parameters, and inputting a DSA configuration and a set of plasma processing parameters for a desired plasma process to the trained AI model, the trained AI model outputting resource allocation information for the DSA configuration. The method further includes allocating resources in the DSA based on the resource allocation information outputted from the trained AI model, and performing a plasma simulation for the desired plasma process using the allocated resources.

And in accordance with yet another embodiment of this disclosure, a method of training an artificial intelligence (AI) model to recommend process adjustments for a plasma process includes providing a training set to the AI model, the training set including results of a plasma simulation executed on a domain-specific computer architecture (DSA) designed for plasma physics computations, and training the AI model using the training set to form a trained AI model, the trained AI model configured to output recommendations for process adjustments to an input plasma process, the process adjustments including changes to processing parameters of the input plasma process. The method further includes adjusting processing parameters for performing a plasma process in a plasma chamber based on the process adjustments, and performing the plasma process on a substrate loaded into the plasma chamber based on adjusted processing parameters.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is an integrated process development method comprising an artificial intelligence (AI) driven simulation in accordance with an embodiment of this disclosure;

FIG. 2 is a diagram of various physics modules used in plasma simulations in accordance with an embodiment of this disclosure;

FIG. 3 is a schematic diagram of domain-specific computer architecture for plasma simulations comprising specialized CPUs for different physics calculations in accordance with an embodiment of this disclosure;

FIG. 4 is a schematic diagram of parallelized domain-specific computer architecture for plasma simulations in accordance with an embodiment of this disclosure;

FIGS. 5A-5B each illustrate a technology stack which may be used to describe opportunities for co-optimization between hardware and software in accordance with embodiments of this disclosure;

FIGS. 6A-6C each illustrate a technology architecture which may be co-designed for optimal plasma simulation performance using the process development method of FIG. 1 and the technology stacks of FIGS. 5A-5B in accordance with embodiments of this disclosure;

FIG. 7 is a flowchart illustrating a method of designing domain-specific computer architecture (DSA) for plasma simulation in accordance with an embodiment of this disclosure;

FIG. 8 is a flowchart illustrating a method of training an AI model for optimizing domain-specific computer architecture (DSA) resource allocation in accordance with an embodiment of this disclosure; and

FIG. 9 is a flowchart illustrating a method of training an artificial intelligence (AI) model to recommend process adjustments for a plasma process in accordance with an embodiment of this disclosure.

### DETAILED DESCRIPTION OF ILLUSTRATIVE EMBODIMENTS

Plasma simulations play a role in semiconductor manufacturing, enabling the optimization of processes and equipment design. However, traditional plasma simulation approaches face significant challenges. These simulations typically utilize extensive expertise in plasma physics, chemistry, and numerical analysis, making them inaccessible to many process engineers. Moreover, the computational complexity of plasma simulations often results in lengthy execution times, sometimes taking several days to complete on general-purpose hardware. This time-consuming nature can impede rapid process development and iteration. Additionally, the multi-physics nature of plasma processes, spanning many scales in time and space, further complicates the simulation process. As a result, the current state of plasma simulations in semiconductor manufacturing often leads to a preference for running physical wafers rather than simulations, potentially slowing down process development and increasing costs. There is a desire for improved systems and methods that can make plasma simulations more accessible to non-experts and significantly reduce simulation time, thereby enhancing the efficiency of semiconductor manufacturing processes.

The systems and methods of this disclosure address several challenges in the field of plasma simulations for semiconductor manufacturing. In various embodiments, the systems and methods reduce the expertise barrier that prevents many process engineers from utilizing plasma simulations effectively. The systems and methods also decrease the long simulation times of conventional plasma simulation methods, which can take several days on general-purpose hardware, making conventional methods impractical for rapid iteration in process development. Additionally, the systems and methods simplify the complexity of setting up and interpreting multi-physics simulations that span many scales in time and space. In one or more embodiments, this disclosure integrates plasma simulations more seamlessly into the process development workflow, enabling engineers to run multiple simulations before processing a single wafer. By addressing these challenges, the systems and methods of this disclosure accelerate equipment and process development, enhance process improvement efforts, and aids in equipment troubleshooting.

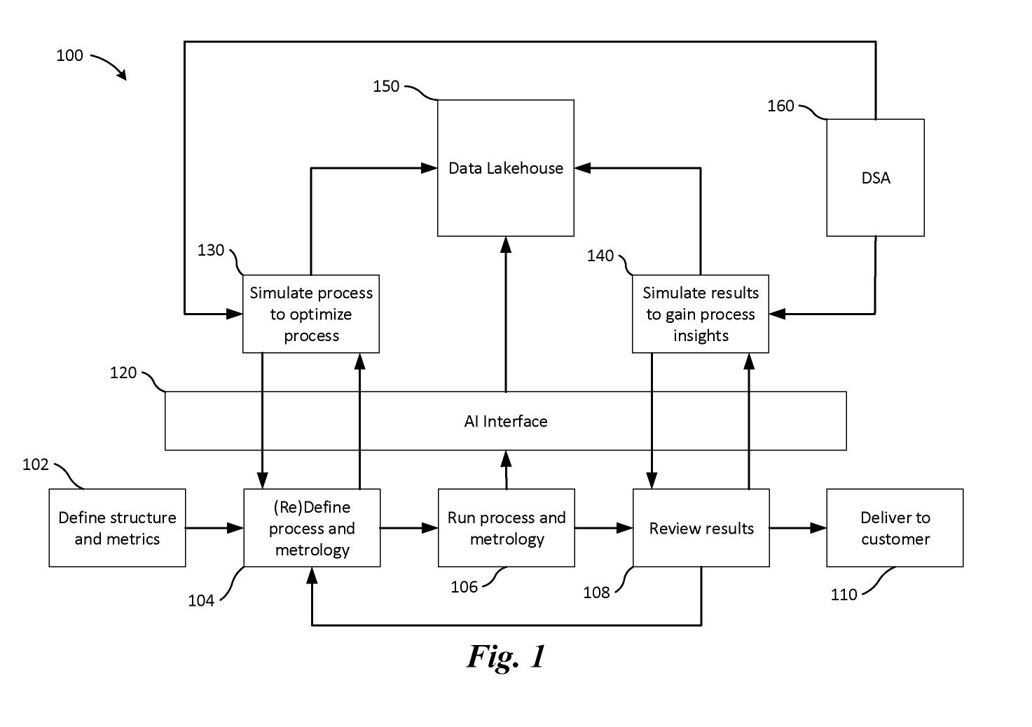

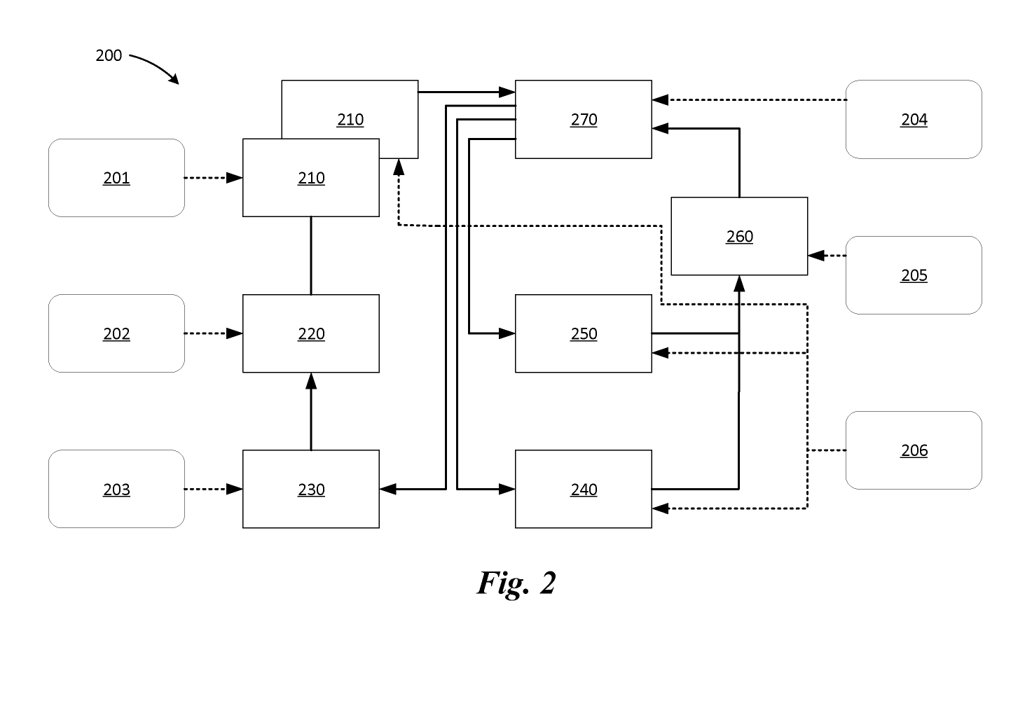

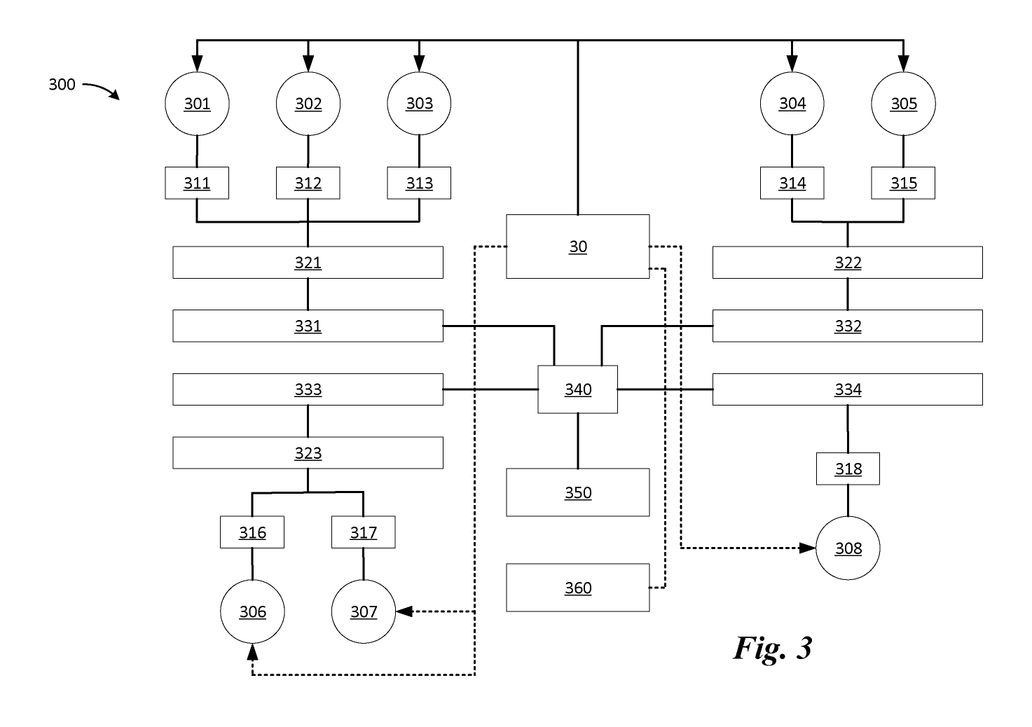

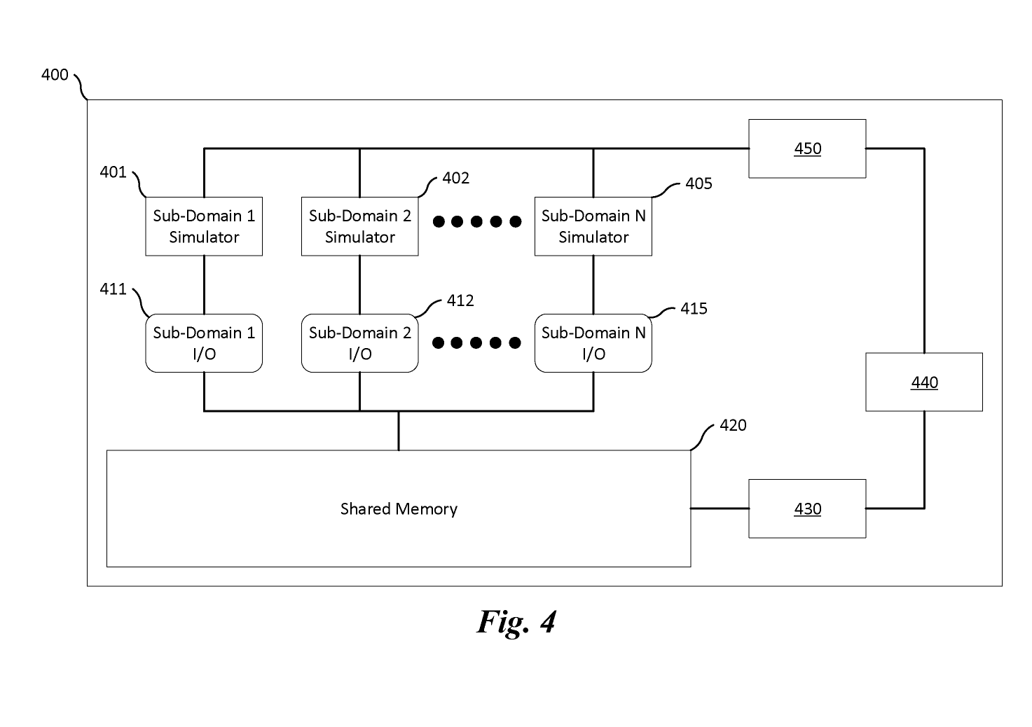

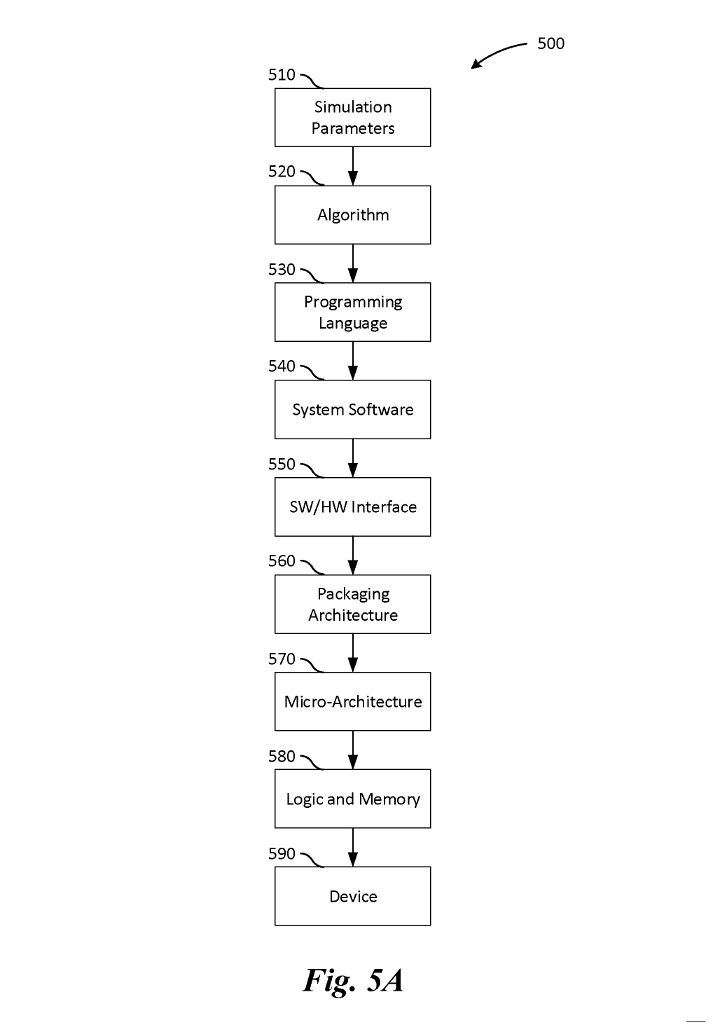

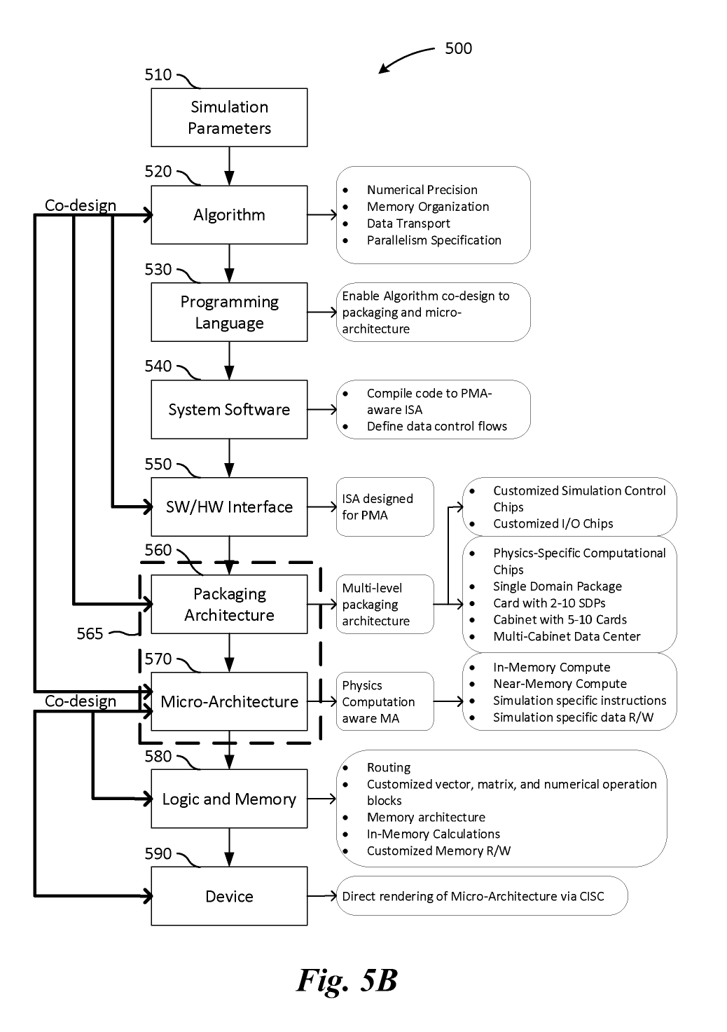

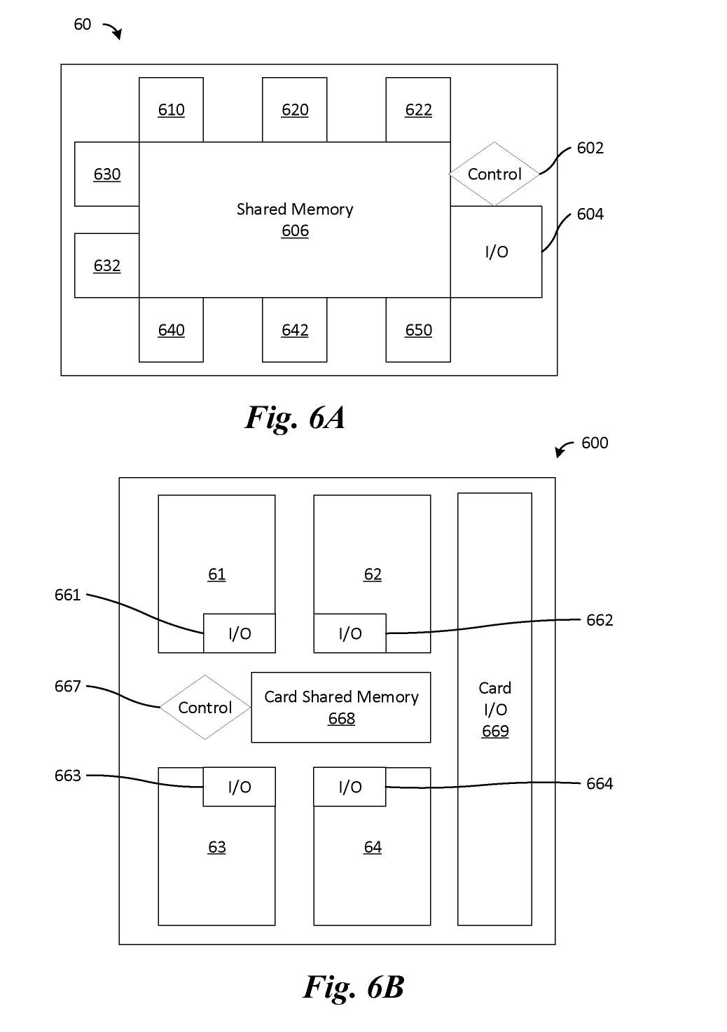

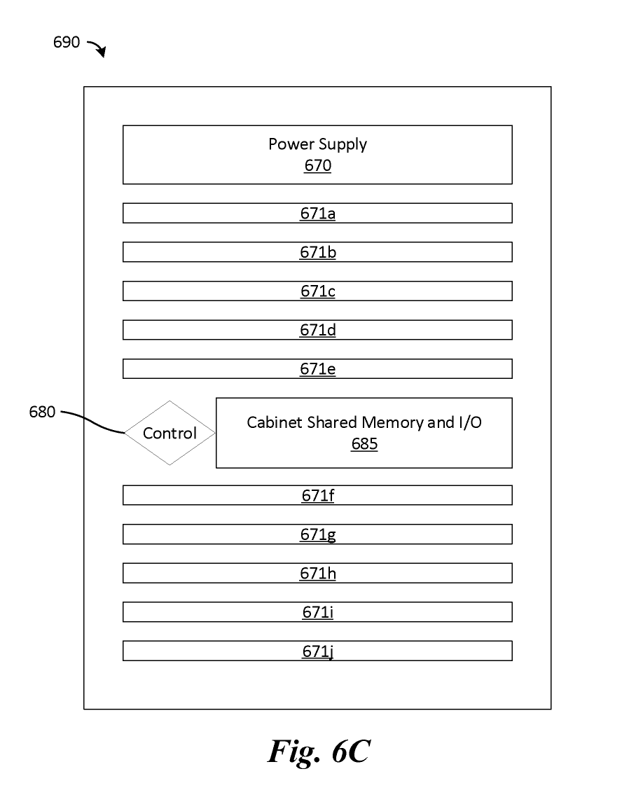

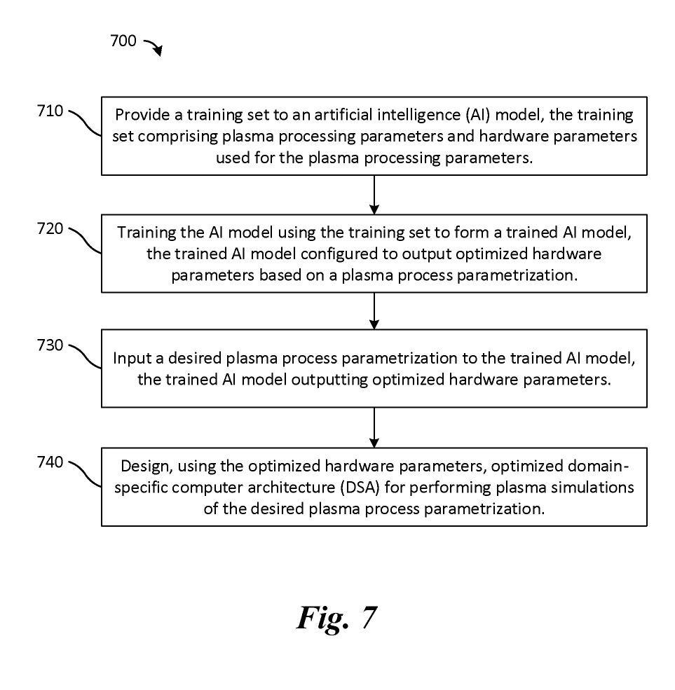

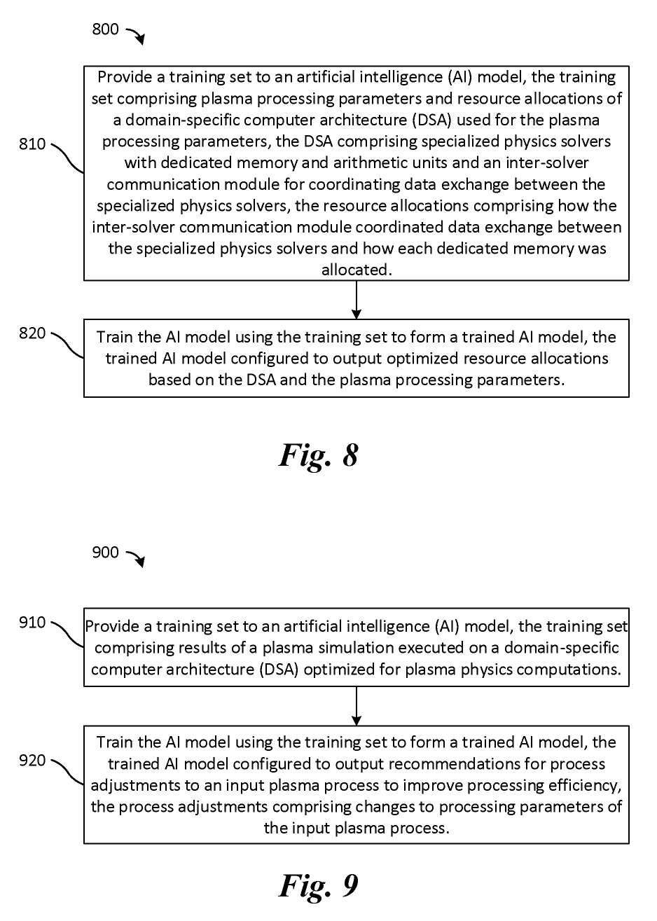

Embodiments provided below describe various methods, apparatuses and systems for performing plasma simulations, and in particular, to methods, apparatuses, and systems that use domain-specific computer architecture (DSA) in combination with an artificial intelligence (AI) interface to perform more efficient and rapid plasma simulations to improve semiconductor fabrication techniques. The following description describes the embodiments. FIG. 1 is an integrated process development method comprising an artificial intelligence (AI) driven simulation. FIG. 2 is used to describe the various physics models which may be used in a plasma simulation. FIG. 3 is a schematic diagram of domain specific architecture for plasma simulations comprising specialized CPUs for different physics calculations. FIG. 4 is a schematic diagram of parallelized domain specific architecture for plasma simulations. Embodiment technology stacks comprising the use and implementation of the domain-specific computer architecture (DSA) for an improved plasma simulation development cycle are illustrated and described using FIGS. 5A-5B. FIGS. 6A-6C illustrate embodiment technology architectures which may be designed using the process development method of FIG. 1 and the technology stacks of FIGS. 5A-5B. FIG. 7 uses a flowchart to describe a method of designing domain-specific computer architecture (DSA) for plasma simulation. And the flowcharts of FIGS. 8-9 illustrate two other example methods of training AI models for improving plasma simulations.

FIG. 1 illustrates a process development method 100 that integrates traditional process development steps with advanced simulation and artificial intelligence (AI) capabilities. As a result, this method may enhance the efficiency and effectiveness of process development in semiconductor manufacturing. Other embodiments may enhance process development for other complex industrial processes.

The process development method 100, in step 102, defines a structure and metrics. In step 102, the goals and parameters of the process (such as a semiconductor fabrication process using a plasma) being developed are established, comprising the desired outcomes and the metrics by which success will be measured. For example, in various embodiments, the desired outcomes may comprise features, or etch rates, or deposition rates, or other fabrication desires for the plasma process to be simulated. In embodiments, the structure may be the fabrication hardware used in the process, such as a plasma tool for etching or depositing.

Following the initial definition in step 102, step 104 defines (or redefines after step 108) a process and metrology. Step 104 allows for the specification or refinement of the process steps and the measurement techniques (the metrology) that will be used to evaluate the process outcomes. For example, processing parameters of the plasma process may be defined, or chemistries used in the plasma process. The flexibility to redefine these elements enables iterative improvement based on insights gained throughout the development cycle. Conventional methods may redefine the process and metrology after running on actual wafers, which is inefficient due to the physical processing which occurs to enhance the processing method. In contrast, the method of this disclosure, through the inclusion of an AI interface 120 and the ability to perform multiple plasma simulations in a short timeframe, may accomplish the same feedback loop using the plasma simulations without multiple trials performed on physical wafers. In various embodiments, the AI interface 120 comprises an AI-powered user interface.

With the process defined and the metrology for determining whether goals were met defined, the process development method 100 proceeds to run the process and the metrology in step 106. Step 106 involves executing the defined process and conducting the specified measurements to gather data on the process performance.

After running the process in step 106, the process development method 100 reviews the results in step 108. In step 108, the data collected from the process run and metrology is analyzed to evaluate the process performance against the defined metrics and goals. After reviewing the results in step 108 and finding the process does not meet the defined metrics and goals, the process development method 100 may determine to use the results to proceed back to step 104 and redefine the process and metrology based on those results, and repeat the previous steps. Otherwise, if the process meets the defined metrics and goals, the process development method 100 proceeds to step 110.

Step 110 delivers the process (which was determined to meet the defined metrics and goals) to the customer. Step 110 represents the point at which the developed process, along with its associated data and insights, is provided to the end-user or customer.

The process development method 100 differs from conventional process development methods by comprising an AI interface 120. This interface serves as a bridge between the traditional process development steps (steps 102, 104, 106, 108, and 110) and advanced simulation and analysis capabilities. The AI interface 120 can interpret results, suggest optimizations, and facilitate communication between different components of the system by using various trained AI models. Conventional methods may run the process and the metrology by using a skilled user to properly configure the hardware, but the process development method 100 of this disclosure enables a user to run the process and the metrology through the AI interface 120 without being highly specialized in the field of plasma simulation and plasma physics.

Connected to the AI interface 120 are two simulation-based optimization steps. The first, box 130, simulates the process in order to optimize the process. The simulation performed in box 130 involves using computational models and AI models to predict process outcomes and suggest improvements before physical runs. The second, box 140, simulates results to gain process insights. The simulation in box 140 uses simulation techniques and an AI model to analyze and interpret the data collected from actual process runs, potentially uncovering patterns or relationships that might not be immediately apparent. Additionally, the simulation in box 140 may use simulation techniques and the AI model to propose process parameters that may result in an improved process.

In an embodiment, the process development method 100 comprises a data lakehouse 150. This component serves as a centralized repository for all data generated throughout the process development cycle, comprising process parameters, metrology results, simulation outputs, and historical data from previous development efforts. The data lakehouse 150 can be accessed by various components of the system to inform decision-making and improve predictions. In one or more embodiments, rather than the data lakehouse 150, the process development method 100 may use other suitable forms of data storage techniques. In various embodiments, the AI interface 120 may use various AI models, which may be trained or refined using the information stored in the data lakehouse 150 to form various training sets and to be referenced by the AI models for further process refinement. For example, the AI models may comprise a deep learning model, a convolutional neural network model, a natural language model, or others. In various embodiments, the AI interface 120 may comprise a text I/O, gesture monitoring via light detectors (such as cameras) or a form of worn device (such as accelerometers and gyroscopes, or microphones for voice-input), vision goggles capable of tracking a user’s eye movements, or other conventional interfaces that enable user interaction.

The process development method 100 also comprises a domain-specific computer architecture (DSA) 160. The DSA 160 represents specialized hardware and software configurations optimized for the specific types of computations and data processing desired in the given process development domain. The DSA 160 can significantly accelerate simulations and data analysis tasks compared to general-purpose computing systems.

By integrating these advanced components with the traditional process development cycle, the method 100 creates a feedback loop that continuously improves process definition, execution, and analysis. The AI interface 120 and simulation capabilities (130, 140) can suggest refinements to the process definition and metrology (step 104) based on both simulated and actual results. This iterative approach, supported by the data lakehouse 150 and DSA 160, can lead to more rapid process optimization and deeper insights into the underlying physics and chemistry of the process.

This integrated approach to process development has the potential to reduce the number of physical experimental runs used, accelerate the overall development timeline, and lead to more robust and optimized processes. The process development method 100 also facilitates the accumulation and leveraging of knowledge across multiple development cycles, potentially leading to broader insights and improvements in related processes.

The process development method 100 described in FIG. 1 provides a high-level overview of how AI, simulation, and specialized hardware can be integrated into the development cycle. FIG. 2 illustrates various hardware modules and physics simulation models which may be used for performing plasma simulations in detail, showing how different aspects of plasma physics are handled within the DSA 160 described in FIG. 1. Optimizing these hardware modules and the plasma simulations enables specialized hardware to accelerate the simulation process to optimize process in step 130 and gain process insights in step 140 as shown in FIG. 1.

FIG. 2 illustrates a block diagram of physics modules 200 involved in plasma simulations. In various embodiments, these modules represent specialized hardware components designed to efficiently solve different aspects of plasma physics. For example, these specialized hardware components may be elements available to the AI interface 120 or the AI models to determine optimized resource allocation for particular plasma simulations.

The physics modules 200 comprise a Boltzmann partial differential equation (PDE) solver hardware 201, which may be used to simulate electron dynamics 210 such as changes in the distribution of electrons in the simulated plasma over time. The Boltzmann PDE solver hardware 201 is used for modeling the behavior of electrons in the plasma. For example, in various embodiments, the Boltzmann PDE solver hardware 201 may be a custom application-specific integrated circuit (ASIC), or some form of a heterogeneous system-on-chip (SoC). Adjacent to the Boltzmann PDE solver hardware 201 is a wave equation PDE solver hardware 202, which works in conjunction with an electromagnetic wave equation solver 220. The wave equation PDE solver hardware 202 and the electromagnetic wave equation solver 220 are used for simulating the propagation of electromagnetic waves within the plasma.

In one or more embodiments, the physics modules 200 comprise an algebraic/ordinary differential equation (ODE) solver hardware 203 to simulate an RF circuit model 230. The algebraic/ODE solver hardware 203 may be used to efficiently compute the electrical characteristics of RF circuits used in plasma generation and control. In other embodiments, the physics modules 200 comprise a fluid dynamics solver, an electromagnetic field solver, a particle-in-cell solver, and a chemical kinetics solver.

The physics modules 200 further comprise a fluid/Poisson PDE solver hardware 204 which may be designed to solve ion-electron-neutral conservation equations 270 in simulations of a plasma for the process being developed using the process development method 100. The fluid/Poisson PDE solver hardware 204 may be used for modeling the fluid-like behavior of the plasma and the electrostatic interactions within it. In various embodiments, the fluid/Poisson PDE solver hardware 204 may be coupled with a reaction rate calculator hardware 205, which computes the rates of various chemical reactions occurring in the plasma being simulated.

In an embodiment, the physics modules 200 comprise a Monte Carlo solver hardware 206 to simulate ion-neutral interactions 240. The probabilistic approach of the Monte Carlo solver hardware 206 allows for accurate modeling of collisions and energy exchanges between ions and neutral particles in the plasma simulations. The physics modules 200 also comprise components for simulating radiation transport 250 and ions and surface reactions 260. These modules are used for understanding how radiation propagates through the plasma and how ions interact with surfaces, respectively.

In various embodiments, the specialized hardware architecture of these physics modules enables parallel processing and optimized computations specific to each physics domain. This approach can significantly reduce simulation times compared to general-purpose hardware, enabling more rapid iteration in plasma process development and optimization.

Further, the modular nature of this architecture allows for flexibility in updating or replacing individual components as simulation techniques or hardware capabilities advance or as the AI models used in the process development method 100 are refined. Additionally, the specialized nature of each module can potentially improve the accuracy of simulations by allowing for more detailed and focused computations in each physics domain. For example, the resources used for a simulation may be drastically different depending on the amount of solvers (corresponding to the amount of physics modules), such as a two-solver plasma simulation comprising density and movement of charge, and for electromagnetic fields. In an embodiment comprising only two-solvers for the plasma simulation, the architecture may only comprise two physics modules that have been parallelized to optimize the plasma simulation and improve simulation speeds.

While FIG. 2 illustrates the various physics modules involved in plasma simulations, it is beneficial to understand how these modules are implemented in hardware to achieve the desired performance improvements. FIG. 3 provides a detailed view of the plasma simulation hardware architecture (or the domain-specific computer architecture (DSA)), demonstrating how each physics module may be realized as a specialized CPU with dedicated caches and shared resources. This hardware implementation is desirable for achieving the acceleration in simulation times that enables the rapid process optimization described in FIG. 1. The specific hardware components and their interactions enable the domain-specific computer architecture (DSA) to translate the theoretical physics modules into a high-performance computing solution for plasma simulations.

FIG. 3 illustrates a block diagram of plasma simulation hardware 300, depicting a specialized architecture designed for efficient plasma simulations. This hardware architecture comprises multiple specialized CPUs, each dedicated to solving specific aspects of plasma physics, along with associated caches and control components.

In various embodiments, the plasma simulation hardware 300 comprises a fluid and Poisson CPU 301, an ion/neutral Monte Carlo (MC) CPU 302, a radiation MC CPU 303, a Maxwell solver CPU 304, a Darwin solver CPU 305, an electron Boltzmann CPU 306, an electron MC CPU 307, and an RF circuit solver CPU 308. Each of these CPUs may be tailored to efficiently handle specific computational tasks related to plasma physics, or for the specific plasma process being simulated in the process development method 100.

The fluid and Poisson CPU 301 may be designed to solve fluid dynamics equations and Poisson's equation for electrostatic potentials. The ion/neutral MC CPU 302 and radiation MC CPU 303 may utilize Monte Carlo methods to simulate ion-neutral interactions and radiation transport, respectively. The Maxwell solver CPU 304 and Darwin solver CPU 305 may be optimized for solving electromagnetic field equations in different regimes, where the Maxwell solver CPU 304 may be a Maxwell equations electromagnetic solver CPU and the Darwin solver CPU 305 may be a Darwin approximation electromagnetic solver CPU.

In one or more embodiments, the electron Boltzmann CPU 306 and electron MC CPU 307 may focus on electron dynamics, with the former solving the Boltzmann equation and the latter using Monte Carlo methods for more detailed electron simulations. The RF circuit solver CPU 308 may be dedicated to simulating the behavior of RF circuits used in plasma generation and control.

In various embodiments, each CPU may have its own cache (311-318) for rapid access to frequently used data. Additionally, this arrangement can significantly reduce memory access times and improve overall simulation performance.

In various embodiments, an inter-solver controller 30 coordinates the operations of the various CPUs, ensuring synchronization and efficient data exchange. Shared caches 321, 322, and 323 facilitate the sharing of common data between different solvers, reducing redundant computations and memory usage.

In an embodiment, the shared caches (321, 322, and 323) may store specific types of solutions, such as ion neutral electric radiation fields solutions 331, electromagnetic fields solutions 332, electron energy distribution function (EEDF) solutions 333, and circuit solver solutions 334. This organization allows for efficient access to these solutions by multiple CPUs as desired during the simulation process.

An inter-solver input/output (I/O) 340 manages data transfer between the different solver units, while a simulation I/O 350 handles input and output for the entire plasma simulation hardware 300. A simulation controller 360 oversees the entire plasma simulation process, coordinating the activities of all components to ensure a coherent and accurate simulation.

This plasma simulation hardware 300, which is specialized hardware architecture (or domain-specific computer architecture (DSA)), enables parallel processing of different aspects of plasma physics, which may significantly speedup simulation times compared to general-purpose (or conventional) hardware. The modular nature of the architecture also provides flexibility for future upgrades or modifications to individual components as simulation techniques or hardware capabilities advance.

While the hardware architecture presented in FIG. 3 provides a powerful platform for plasma simulations, many real-world applications desire the ability to simulate larger or more complex plasma systems. To address this desire, the architecture may be scaled up through parallelization. FIG. 4 illustrates how the plasma simulation hardware 300 can be parallelized to handle multiple sub-domains simultaneously. This parallelized architecture builds upon the specialized CPUs and memory structures shown in FIG. 3, distributing them across multiple sub-domain simulators. The parallelized structure of FIG. 4 may also be used to describe how the plasma simulation capabilities can be expanded to address more extensive and intricate plasma systems, further enhancing the process optimization potential described in FIG. 1.

FIG. 4 illustrates a parallelized architecture 400 for plasma simulations, designed to handle large-scale simulations by dividing the computational domain into multiple sub-domains. This approach further enables efficient distribution of computational resources and can significantly reduce overall simulation times.

In various embodiments, the parallelized architecture 400 comprises multiple sub-domain simulators, each responsible for simulating a portion of the overall plasma domain. The parallelized architecture comprises sub-domain 1 simulator 401, sub-domain 2 simulator 402, and may extend to sub-domain N simulator 405. The ability for the number of sub-domain simulators to extend to N domains enables the architecture to accommodate a variable number of sub-domains based on the simulation specifications and available computational resources.

In various embodiments, each sub-domain simulator may be paired with an input/output (I/O) component. In those embodiments, the parallelized architecture 400 comprises sub-domain 1 I/O 411, sub-domain 2 I/O 412, and sub-domain N I/O 415, which may be configured to handle the input and output operations for their respective simulators. These I/O components manage the flow of data between the sub-domain simulators and other parts of the system, such as a shared memory and an overall simulation controller.

In one or more embodiments, a shared memory 420 may be used to facilitate efficient data exchange between the sub-domain simulators. The shared memory 420 allows for rapid communication of boundary conditions and other relevant information between adjacent sub-domains, ensuring consistency across the entire simulation domain.

An I/O to solution component 430 may be used to manage the aggregation of results from all sub-domain simulators, compiling them into a coherent overall solution for the plasma simulation. Additionally, the I/O to solution component 430 may be used in synthesizing the distributed computations into meaningful results that can be interpreted and analyzed. For example, the I/O to solution component 430 may synthesize the distributed computations into meaningful results which may be interpreted and analyzed by the AI interface 120, which may then communicate that information in a reasonable format to the user of the DSA performing the plasma simulation using the process development method 100 of this disclosure.

The parallelized architecture 400 further comprises a simulation controller 440, where the simulation controller 440 oversees the entire parallelized simulation process. The simulation controller 440 coordinates the activities of all sub-domain simulators, manages the distribution of computational tasks, and ensures synchronization between different parts of the simulation. The simulation controller 440 can dynamically adjust the workload distribution based on the complexity of different regions in the plasma domain, potentially leading to more efficient use of computational resources.

The parallelized architecture further comprises an I/O to sub-domain simulators component 450, which may be used as an interface between the simulation controller and the individual sub-domain simulators. The I/O to sub-domain simulators component 450 manages the flow of control signals, initial conditions, and other pertinent information from the controller to the simulators, ensuring that each sub-domain operates in harmony with the overall simulation objectives.

In an embodiment, the parallelized architecture 400 enables scalable plasma simulations. By increasing the number of sub-domain simulators, larger or more complex plasma systems can be simulated without a proportional increase in simulation time. This scalability can be particularly beneficial for simulating industrial-scale plasma processes or complex plasma phenomena that utilize high spatial resolution. Additionally, the coordination of resources and the suggested parallelization of existing resources may be automatically selected and configured by the AI models used in the AI interface 120 or by the other AI models used for optimizing the plasma simulations in the process development method 100 of this disclosure.

The modular nature of this architecture also provides flexibility for heterogeneous computing environments. Different sub-domain simulators could potentially utilize different types of computational hardware, optimized for the specific physics occurring in that sub-domain. This could lead to further improvements in simulation efficiency and accuracy.

In various embodiments, the parallelized architecture 400 illustrated in FIG. 4 can be applied to scale up the plasma simulation hardware described in FIG. 3. Each sub-domain simulator (401, 402, 405) can be implemented as a complete set of the specialized CPUs and associated caches shown in FIG. 3. For example, sub-domain 1 simulator 401 could contain its own fluid and Poisson CPU, ion/neutral MC CPU, radiation MC CPU, Maxwell solver CPU, and other components, all working on a specific portion of the overall plasma domain for the plasma simulation. The shared memory 420 in FIG. 4 can be used to exchange information between these sub-domain hardware sets, such as boundary conditions or particle data for particles moving between sub-domains. The simulation controller 440 in FIG. 4 would take on an expanded role, coordinating not just between sub-domains, but also between the different specialized CPUs within each sub-domain. This approach allows for efficient scaling of the simulation to larger plasma systems or higher resolutions by adding more instances of the specialized hardware, each handling a portion of the overall simulation domain. FIGS. 5A-5B may be used to describe how the process development method 100, the physics modules which may be used in the plasma simulations, and the domain-specific computer architecture may be combined to increase the speed of plasma simulations using AI models and an AI interface.

FIGS. 5A-5B show a technology stack 500 which may be used to describe opportunities for algorithm-hardware co-optimization, where each level of the technology stack 500 may be a technology co-optimized for plasma simulations. For example, the technology stack 500 may be used to describe a set of technologies optimized for a multi-physics simulation, where simulation parameters determine the description of different technologies used to implement and optimize that particular plasma simulation, how the simulation parameters are implemented on a DSA (computer), and the design of the DSA. Additionally, FIGS. 5A-5B illustrate embodiment methods for algorithm/CPU technology co-optimization using artificial intelligence (AI) in accordance with embodiments of this disclosure. Further, the technology stack 500 of FIGS. 5A-5B may use multiple artificial intelligence (AI) models trained to optimize particular aspects of the algorithm/CPU technology co-optimization, and may co-design various technology layers of the technology stack 500.

FIG. 5A illustrates a technology stack 500 used to describe the opportunities for co-optimization between the hardware and the software which utilizes artificial intelligence (AI) for algorithm and CPU technology co-optimization. The technology stack 500 comprises multiple technology levels that flow from top to bottom, representing the process of optimizing various aspects of a computing system for plasma simulation, such as the DSA 160 of FIG. 1. Though referred to as a technology stack, the technology stack 500 may also be referred to as a stack, or as an abstraction stack.

At the top of the technology stack 500, level 510 represents the simulation parameters. These parameters serve as the starting point for the optimization process, defining the specific desires and constraints of the plasma simulation for the process desired to be performed, such as an etching or deposition process using the plasma. For example, the simulation parameters may comprise processing rates, temperatures, RF power of a plasma chamber, or other parameters for the plasma simulation. The simulation parameters may also comprise equations describing the physics of a corresponding plasma simulation, the boundary and initial conditions, the forcing functions, and the material properties and reaction rates.

Following the simulation parameters, level 520 focuses on the algorithm itself. In level 520, the algorithm determines how the simulation may be translated into discrete mathematical domains that the DSA is capable of handling, and the numerical steps to reach a solution. Further, the algorithm may further comprise specifications for iteration and convergence control.

Level 530 defines the programming language used to perform the algorithms of the plasma simulation. The programming language may be a rendering of the algorithms in a format suitable for submission for compilation. And level 540 focuses on the system software. In various embodiments, the system software comprises the compiler, which may be used to translate the simulation parameters of level 510 and the algorithms of level 520 into an instruction set that the DSA’s hardware understands. In one or more embodiments, the system software also comprises system drivers which perform tasks of reading and writing data, and starting the program.

The technology stack 500 further comprises level 550, which focuses on a software/hardware (SW/HW) interface. In multiple embodiments, the SW/HW interface of level 550 may be a low-level description of the DSA’s capabilities, which may be referred to as an instruction set architecture (ISA). The simulation parameters may be translated into the ISA language.

Level 560 of the technology stack 500 comprises packaging architecture. In level 560, the packaging architecture specifies the hardware layout of the DSA. In various embodiments, the hardware layout comprises chips that perform computations, store data, and data transfer channels. Additionally, the packaging architecture may determine integrations of chips into multi-physics chip sets (MPCSs) units and the integration of MPCSs into clusters for parallel execution. Examples are described using FIGS. 6A-6C below.

The technology stack 500 also comprises level 570, which determines micro architecture for the DSA. As an example, the micro architecture determines the functional organization of the chips that perform computations for the plasma simulation, control of the chips, I/O, and shared memory.

In various embodiments, level 580 focuses on logic and memory of the DSA. In one or more embodiments, the logic and memory of level 580 determines the individual logic and memory blocks as they are distributed on a chip and the interconnections between them. In those embodiments, the determination of those distributions are dimensionally accurate. For example, the distribution may represent the physical location and extent of logical elements on the chip. And level 590 determines the device. In level 590, the device describes the 3D structure of transistors, memory, and interconnects for the DSA. In various embodiments, the technology stack 500 may be used to design the DSA 160 of FIG. 1.

Now referring to FIG. 5B, the technology stack 500 is described in further detail with descriptions of the use of AI models to perform the various aspects of the design of the DSA and determination of optimal programming languages and technologies for a corresponding plasma simulation parametrization. For optimized performance, elements of the technology stack may be both individually optimized, and co-optimized for particular plasma simulations. This specialization may be achieved with a cost of loss of generality: the DSA may be inefficient when used to solve other types of simulations. As illustrated in FIG. 5B, the packaging architecture level 560 and the micro-architecture level 570 may be collectively referred to as a packaging and micro-architecture (PMA) 565.

At the simulation parameters level 510, the process development may take in a simulation statement from a user and then decompose the multi-physics simulation into individual physics models and how they may interact. For example, ion transport may be mobility, or diffusion with mobility. The simulation may be specified by a very specific syntax, which facilitates the automatic linkage with the algorithm level 520. The simulation specification may comprise specifications for what physics models comprise the solution and how they interact with each other. As an example, for the electron transport, the user may select diffusion, drift-diffusion, Monte-Carlo, or Boltzmann (either full Boltzmann, or some approximation). Further, the simulation statement may comprise meshing of the physical domains, where the meshing of the physical domains comprise specifications that apply to plasma simulations. For example, sheath regions versus plasma bulk regions may specify different mesh sizes. Additionally, within the same region, different physical simulations may specify different meshes accordingly. An example is the different meshes for electromagnetic compared to fluid equations. In one or more embodiments, software tools may be provided to aid the user in defining these meshes, such as using an AI model to assist the tools for building meshes.

In various embodiments, the algorithm level 520 may be augmented by a problem specific numerical precision model that enables the simulation to be performed in integer arithmetic. Additionally, memory organization, multi-physics, and physical domain parallelism and data transport may also be specified at the algorithm level 520. These features may be directly supported via co-optimization with lower stack levels. As illustrated in FIG. 5B, the algorithm level 520 may be co-designed with the SW/HW interface level 550, the packing architecture level 560, and the micro-architecture level 570.

The algorithm may express the method of performing the plasma simulation. Additionally, the algorithm may specify the parallelization over the physical domain via sub-domains. In various embodiments, the algorithm may also specify details of numerical representations and how they evolve over the simulation. The algorithm may also specify the meshing of the physical domain and sub-domains. Parts of the algorithm may be automatically derived from the simulation specification.

In one or more embodiments, the algorithm level 520 may define solvers for each specific physics model, such as numerical with some part of AI. Each algorithm may specify a numerical representation, and how that may be adjusted, or updated as the solution iterates. In multiple embodiments, the algorithm may define how the data is stored in the memory. In general, the memory may be accessed as blocks of data, but the algorithm may define the blocks and define how they are accessed and pre-fetched as the algorithm executes.

In further embodiments, the algorithm level 520 may specify iteration and convergence within a multi-physics module across multiple multi-physics modules into which the physical domain is subdivided. The algorithm may also specify how data is synchronized between different physics problems and different physical domains.

In one or more embodiments, the programming language level 530 further comprises features to support the algorithm features, but may hide the implementation of integer arithmetic from the user. The programming language level 530 may be co-designed with the ISA. Further, the programming language 530 enables algorithm co-design to the packaging architecture level 560 and the micro-architecture level 570. In various embodiments, the programming level 530 may translate the algorithm definition into code that may be compiled. The programming languages may be of the C-family type, such as C++, Rust, or Go. The programming language level 530 may facilitate the translation of arithmetic operations using mixed precision to underlying hardware using the specified mixed-precision specifications. Additionally, syntax customized to express the algorithm concisely and precisely may be facilitated by the programming language level 530, which may comprise data structures, movement of data, iteration, and control commands.

At the system level 540, the compiler and the ISA enable the implementation of the algorithm specifications at a hardware level. Additionally, the system drivers may support the memory organization and data transport as specified in the algorithm. The system level 540 may also compile code to PMA 565 aware ISA, and define data control flows. In various embodiments, the system software comprises a compiler to translate the source code into machine code suitable for each physics module hardware. And the compiler may be co-optimized with the SW/HW interface level 550 to take advantage of the ISA. The system software further comprises system services for managing the execution of the simulation, which may comprise control, data storage in memory, data transfer within the multi-physics modules and between multi-physics modules.

At the SW/HW interface level 550, the ISA supports the new algorithm specifications and how they may be transmitted via the compiler. And as illustrated in FIG. 5B, the SW/HW interface level 550 may be co-designed with the algorithm level 520. The SW/HW interface level 550 specifies the ISA that the CPU may understand, where the compiler transforms the algorithm into ISA instructions. In various embodiments, the ISA may be optimized for the plasma simulation. For example, a 3-operand to compute second order difference. If the algorithm specifies the operands be in adjacent registers, or in some other specific relative position, only one register may be supplied. Other customizations may focus on the implementations of the algorithms to solve the partial differential equations, Monte Carlo simulations, and other techniques, such as discrete Fourier transforms.

Still referring to FIG. 5B, the packaging architecture level 560 of the PMA 565, at an abstract level, may be described at the algorithm level 520 and the programming language level 530 and thus the plasma simulation can be tightly coupled with the packaging architecture. The packaging architecture level 560 may comprise multi-level packaging architecture, which comprises customized simulation control chips and customized I/O chips. In various embodiments, the multi-level packaging architecture may further comprise physics-specific computational chips, single domain packaging, cards comprising 2-10 SDPs, cabinets comprising 5-10 cards, or multi-cabinet data centers. The packaging architecture level 560 may be further described using FIGS. 6A-6C below.

In one or more embodiments, the packing level 560 may reflect two different types of parallelism: multi-physics parallelism, or domain parallelism architecture. In domain parallelism architecture, the packing architecture level 560 optimizes the control, data paths, and synchronization. Additionally, the shared memory may facilitate data exchange between domains. Its architecture and I/O may be customized to the plasma simulation. In multi-physics parallelism architecture, the packing architecture level 560 optimizes the control, data paths, and synchronization. And additionally, the shared memory may facilitate data exchange between physics modules, where its architecture and I/O may also be customized to the plasma simulation. Further details of the multi-physics parallelism are described using FIGS. 6A-6C below.

In the technology stack 500, at the micro-architecture level 570, the functional organization of each chip may be optimized for physics simulation, simulation control, or data access. The micro-architecture level 570 may be co-designed with the algorithm level 520, and the micro-architecture level 570 may be co-designed in tandem with the logic and memory level 580, and the device level 590. In various embodiments, the algorithm and programming language features are directly supported in the micro-architecture level 570, thus increasing the simulation speed. In one or more embodiments, the micro-architecture level 570 may comprise physics computation aware of the micro-architecture. Further, the micro-architecture level 570 may comprise in-memory compute, near-memory compute, simulation specific instructions, and simulation specific data R/W.

The micro-architecture of individual physics simulation chips (PSCs) may comprise different micro-architecture based on the physics problems that they are optimized to perform. AI models may be trained and used to assist in the design and specification of the micro-architecture, such as the embedding of memory within the compute units.

At the logic and memory level 580 of the technology stack 500, the logic and memory blocks may be optimized for the type of operations performed in the plasma simulation and to the numerical precision used. The logic may also support complex domain specific instructions such as second-order differences, discrete fourier transforms, and fast polynomial evaluation instructions. Further, the logic and memory level 580 may comprise routing, customized vector, matrix, and numerical operations blocks, memory architecture, in-memory calculations, and customized memory read/write (R/W).

At the logic and memory level 580, the logic may implement complex instruction sets suitable for the problem and for the mixed precision computation. Additionally, AI technology may be used to optimize the logic design, placement, and routing. The memory may be optimized for the numerical operations performed for plasma simulations. For example, the memory may be organized in rows and columns, where a row of memory stores a sequence of numbers that share the exponent and high precision bits. Thus, they are stored separately, and only the low precision bits common to each number are stored in contiguous locations. Further, a read of the memory may be performed on a whole row, and during the read, the read buffer may perform simple operations such as offset or multiply. These operations may be performed before data is sent to the CPU.

And at the device level 590 of the technology stack 500, the devices used may proceed from FPGA during early development cycles and proceed to custom silicon at later stages after verifying the design of the DSA for a corresponding plasma simulation. In various embodiments, direct rendering of the micro-architecture determined from the micro-architecture level 570 may be performed via CISC. Additionally, the device level 590 may be optimized for the calculations and data movement that are relevant to the plasma simulations.

In the technology stack 500, trained AI models may be used to aid the development and implementation of a plasma simulation and a DSA for performing the plasma simulation. For example, in the specification of the simulation problem, AI may aid mesh building. Additionally, the AI models may aid in the design of the packaging architecture, where the AI may aid in optimizing the combination and performance of the sub-components. In the micro-architecture level 570, the trained AI models may assist the design of the PSC, control, I/O, and memory. Further, the trained AI models may aid in the design of the logic and memory level 580, such as the layout and routing. And the trained AI models, at the device level 590, may be used to optimize the design of devices (or DSAs) for optimal performance and increased plasma simulation speeds, which is a benefit of the methods of this disclosure.

By incorporating AI into the co-optimization process, the technology stack 500 in FIG. 5B can potentially achieve even greater performance improvements for plasma simulations, balancing computational speed with numerical accuracy as desired for different aspects of the simulation. The methods for training the various AI models used in the technology stack 500 of either FIGS. 5A-5B may be described using the flowcharts of FIGS. 7-9.

FIGS. 6A-6C each illustrate a technology architecture (or packaging architecture) which may be co-designed for optimal plasma simulation performance using the process development method 100 of FIG. 1 and the technology stacks 500 of FIGS. 5A-5B. Plasma simulations are inherently multi-physical, which may benefit from the use of parallel separate physics-specific chips (PSCs) with the support of additional memory. And a plasma simulation may be performed by exchanging data between various PSCs until convergence. In various embodiments, the DSA designed for a particular plasma simulation may use a single multi-physics chip set (MPCS), such as illustrated in FIG. 6A. In other embodiments, the DSA designed for other plasma simulations may benefit from using various MPCSs packaged in a computational card, such as illustrated in FIG. 6B. And in even further embodiments, the DSA designed for further particular plasma simulations may benefit from using a computational cabinet comprising multiple computational cards, such as illustrated in FIG. 6C.

FIG. 6A illustrates a multi-physics chip set (MPCS) 60, FIG. 6B illustrates a card 600 comprising various MPCSs, and FIG. 6C illustrates a cabinet 690 comprising various cards. The MPCS 60, the card 600, and the cabinet 690 may each be an embodiment DSA designed using the process development method 100 of FIG. 1 and the technology stack 500 of FIGS. 5A-5B. In various embodiments, the design of the MPCS 60, the card 600, and the cabinet 690 may be assisted by the AI models of this disclosure.

FIG. 6A illustrates the MPCS 60 comprising various physics-specific chips (PSCs) 610, 620, 622, 630, 632, 640, 642, and 650. In various embodiments, PSC 610 may be designed to perform physics calculations of a particular physics model for the physics simulation, while PSC 620 and PSC 622 may be designed to perform a different set of physics calculations of a different physics model for the physics simulation which may benefit from using multiple PSCs. Similarly, PSC 640 and PSC 642 may be configured to perform physics calculations of another physics model for the physics simulation that benefits from using multiple PSCs. And PSC 650 may perform yet another physics calculation for the physics simulation, but only using one PSC. Other embodiments may use less or more PSCs in tandem, which may be determined using the AI models of this disclosure. The MPCS 60 is an example, and other embodiments may use more or less PSCs to optimize the plasma simulations being performed. In an embodiment, the MPCS 60 may be the parallelized architecture 400 of FIG. 4.

Still referring to FIG. 6A, the MPCS 60 further comprises a shared memory 606, a control 602, and a I/O 604. The shared memory 606 may be any suitable shared memory between the various PSCs of the MPCS 60, and may be used as similarly described above for the shared memory 420 of FIG. 4. The control 602 may be used to control the operation of the PSCs 610, 620, 622, 630, 632, 640, 642, and 650, and may be used as previously described for the simulation controller 440 of FIG. 4. And similarly, the I/O 604 may be any suitable I/O technology to enable the input and output of information from the MPCS 60, such as the description of the I/O to sub-domain simulators component 450 of FIG. 4. The control 602 controls the simulation at the chip set level, the I/O controls communication between chip sets, and the shared memory 606 stores temporary data and exchanges data between computational units.

In various embodiments, the MPCS 60 may be the parallelized architecture 400 of FIG. 4, or the plasma simulation hardware 300 of FIG. 3. In one or more embodiments, for a particular plasma simulation, the MPCS 60 may be the DSA 160 of the process development method 100 in FIG. 1. Larger physics simulations may be distributed across multiple MPCS in a computational card, such as the card 600 illustrated in FIG. 6B.

FIG. 6B illustrates the card 600 which may be used to perform plasma simulations larger than may be feasible to perform on a single MPCS. The card 600 comprises a first MPCS 61, a second MPCS 62, a third MPCS 63, and a fourth MPCS 64, where each of the MPCSs (61, 62, 63, and 64) may be optimized for performing particular calculations of the physics simulation. The card 600 further comprises a card control 667, a card shared memory 668, and a card I/O 669.

The card 600 is an example embodiment, other embodiments may comprise more or less MPCSs, such as embodiments comprising between 2 to 8 MPCSs. Each of the MPCSs comprise a corresponding I/O. The first MPCS 61 comprises a first I/O 661 to communicate with the card control 667 and the card shared memory 668. The second MPCS 62 comprises a second I/O 662 to communicate with the card control 667 and the card shared memory 668. The third MPCS 63 comprises a third I/O 663 to communicate with the card control 667 and the card shared memory 668. And the fourth MPCS 64 comprises a fourth I/O 664 to communicate with the card control 667 and the card shared memory 668. In an embodiment, the MPCSs may be variations of the MPCS 60 of FIG. 6A. In embodiments, the card I/O 669 may be facilitate data transfer between the various I/Os of the MPCSs and a host of the card 600.

In various embodiments, the MPCSs (61, 62, 63, and 64) may be side-by-side on an interposer (such as in 2.5D packaging). In other embodiments, the control and shared memory may be disposed over the top of the MPCSs (such as in 3D packaging). In one or more embodiments, the card control 667 may manage the operation of the MPCSs (61, 62, 63, and 64) and synchronize their activity. Further, the card shared memory 668 may be used to store temporary data used by the MPCSs. In one or more embodiments, for a particular plasma simulation, the card 600 may be the DSA 160 of the process development method 100 in FIG. 1.

In various embodiments, the process development method may determine an optimized DSA be a cabinet comprising multiple computational cards, such as the cabinet 690 of FIG. 6C. The cabinet 690 may be used in embodiment plasma simulations that are larger than plasma simulations which may be performed on individual cards, such as the card 600. In FIG. 6C, the cabinet 690 comprises a power supply 670, a cabinet control 680, a cabinet shared memory and I/O 685, and various computational cards 671a-j. The power supply 670 may be any suitable power supply for supplying operational power to the various computational cards 671a-j and other components of the cabinet 690. The cabinet control 680 may be used to facilitate the operation of the various computational cards 671a-j, and the cabinet shared memory and I/O 685 may be used to store temporary data and transmit the data between the various computational cards 671a-j. The various computational cards 671a-j may each be individually optimized and designed for unique physics calculations. In one embodiment, one, multiple, or all of the various computational cards 671a-j may be the card 600. In other embodiments, each of the various computational cards 671a-j may comprise cards with different amounts of MPCSs, each comprising associated amounts of PSCs.

In various embodiments, different DSAs may comprise a cabinet with different amounts of computational cards. For example, some embodiments may use a DSA where the DSA comprises a cabinet with between 2 to 20 computational cards. In various embodiments, the cabinet 690 is an electronics rack comprising ventilation for heat management, and may further comprise fans or other heat dissipation devices. In one or more embodiments, for a particular plasma simulation, the cabinet 690 may be the DSA 160 of the process development method 100 in FIG. 1.

FIG. 7 is a flowchart illustrating an example method of designing domain-specific computer architecture (DSA) in accordance with embodiments of the disclosure. The method of FIG. 7 may be combined with other methods and performed using the systems and apparatuses as described herein. For example, the method of FIG. 7 may be used to design the DSA of FIG. 3 and used in the technology stack 500 illustrated in FIGS. 5A-5B. Although shown in a logical order, the arrangement and numbering of the steps of FIG. 7 are not intended to be limiting.

Referring to FIG. 7, step 710 of a method 700 of designing domain-specific computer architecture for plasma simulation provides a training set to an artificial intelligence (AI) model, the training set comprising plasma processing parameters and hardware parameters used for the plasma processing parameters. For example, the training set may comprise processing times, powering specifications for controlling the plasma, and other plasma processing parameters which may have been performed on previous fabrication processes. After, the method 700 trains the AI model using the training set to form a trained AI model in step 720. In step 720, the trained AI model is configured to output optimized hardware parameters based on a plasma process parametrization, such as the simulation parameters of level 510 in FIGS. 5A and 5B. Step 730 of the method 700 inputs a desired plasma process parametrization to the trained AI model, the trained AI model outputting optimized hardware parameters. And the method 700, in step 740, designs, using the optimized hardware parameters, optimized DSA for performing plasma simulations of the desired plasma process parametrization, such as by using level 565 to form the device in level 590 of FIG. 5B.

FIGS. 8-9 are flowcharts illustrating example methods of training artificial intelligence (AI) models in accordance with embodiments of the disclosure. The methods of FIGS. 8-9 may be combined with other methods and performed using the systems and apparatuses as described herein. For example, the methods of FIGS. 8-9 may be implemented in the DSA of FIG. 3 and used in the technology stack 500 illustrated in FIGS. 5A-5B. Although shown in a logical order, the arrangement and numbering of the steps of FIGS. 8-9 are not intended to be limiting.

Referring to FIG. 8, step 810 of a method 800 of training an AI model provides a training set to an artificial intelligence (AI) model. The training set comprises plasma processing parameters and resource allocations of the DSA used for the plasma processing parameters. The DSA comprises specialized physics solvers with dedicated memory and arithmetic units and an inter-solver communication module (or inter-solver communication circuit) for coordinating data exchange between the specialized physics solvers. In various embodiments, the specialized physics solvers may be the physics solvers described in FIG. 2 and in the DSA of FIG. 3. And the resource allocations comprise how the inter-solver communication module coordinated data exchange between the specialized physics solvers and how each dedicated memory was allocated, such as the caches of FIG. 3. After, the method 800 trains the AI model using the training set to form a trained AI model in step 820. The trained AI model is configured to output optimized resource allocations (or resource allocation information) based on the DSA and the plasma processing parameters. For example, levels 550, 560, and 570 of FIG. 5A-5B may use the trained AI model to optimize the resource allocation for the logic and memory design in level 580. In an embodiment, training the AI model comprises using a reinforcement learning algorithm to optimize a reward function, the reward function based on at least one of: simulation accuracy, simulation speed, and power consumption of the DSA during simulation.

Now referring to FIG. 9, step 910 of a method 900 of training an artificial intelligence (AI) model to recommend process adjustments for a plasma process provides a training set to the AI model, the training set comprising results of a plasma simulation executed on a domain-specific computer architecture (DSA) optimized for plasma physics computations. After, in step 920, the method 900 trains the AI model using the training set to form a trained AI model, the trained AI model configured to output recommendations for process adjustments to an input plasma process to improve processing efficiency. The process adjustments comprise changes to processing parameters of the input plasma process.

In various embodiments, the trained AI model described in FIG. 9 may be used in the levels of FIGS. 5A-5B, and in the process development method 100 of FIG. 1. In various embodiments, the trained AI model may be validated by inputting a test plasma process to the trained AI model, receiving recommended process adjustments from the trained AI model, executing a plasma simulation of the test plasma process with the recommended process adjustments on the DSA, and comparing results of the plasma simulation to predetermined performance metrics.

Example embodiments of the invention are described below. Other embodiments can also be understood from the entirety of the specification as well as the claims filed herein.

Example 1. A domain-specific computer architecture for plasma simulations includes specialized solvers for different physics domains in plasma simulation, the specialized solvers including one or more processors and a memory including a program to be executed in the one or more processors, the program including instructions for solving the different physics domains in plasma simulation. The domain-specific computer architecture further includes a plurality of dedicated memory devices, where each of the plurality of dedicated memory devices is associated to one of the specialized solvers. And the domain-specific computer architecture further includes an inter-solver controller for managing data flow and synchronization between the specialized solvers, and a simulator-level controller for coordinating overall simulation execution. In some embodiments, by using the domain-specific computer architecture optimized for a particular plasma simulation and an artificial intelligence (AI) powered user interface to input and perform the particular plasma simulation through parallelized computer architecture, the domain-specific computer architecture can advantageously reduce the expertise barrier that prevents many process engineers from utilizing plasma simulations effectively, decrease the long simulation times of conventional plasma simulation methods, and simplify the complexity of setting up and interpreting multi-physics simulations that span many scales in time and space.

Example 2. The domain-specific computer architecture of example 1, where the specialized solvers include an electro-hydrodynamic solver, a Maxwell equation solver, a Monte Carlo collision solver, and an algebraic-differential equation solver, where each are designed for specific plasma physics calculations and configured to operate with variable precision based on simulation specifications.

Example 3. The domain-specific computer architecture of one of examples 1 or 2, where the Maxwell equation solver includes a Poisson solver, an Ampere solver, a Darwin solver, or a full Maxwell equation solver.

Example 4. The domain-specific computer architecture of one of examples 1 to 3, where the electro-hydrodynamic solver includes a full fluid solver, a full fluid solver coupled with a Poisson solver, a drift-diffusion solver, or a drift-diffusion solver coupled with the Poisson solver.

Example 5. The domain-specific computer architecture of one of examples 1 to 4, where each dedicated memory device includes a high-bandwidth local cache for frequently accessed data, a larger capacity main memory for storing intermediate results, and a direct memory access controller for efficient data transfer between solvers.

Example 6. The domain-specific computer architecture of one of examples 1 to 5, where the inter-solver controller is configured to implement a distributed shared memory protocol for parallel processing across multiple solver units, dynamically adjust data exchange rates between solvers based on simulation phase and computational load, and detect and resolve data dependencies to adjust simulation workflow.

Example 7. The domain-specific computer architecture of one of examples 1 to 6, further including a reconfigurable logic array that can be dynamically adjusted for different plasma simulation scenarios, specialized arithmetic units designed for efficient execution of plasma physics calculations, and a heterogeneous integration layer that allows for future hardware upgrades without significant software modifications.

Example 8. The domain-specific computer architecture of one of examples 1 to 7, further including an AI co-processor that assists in runtime modification of solver parameters based on intermediate simulation results, performs real-time analysis of simulation data to detect anomalies or convergence issues, and interfaces with external AI-powered user interfaces to facilitate intelligent simulation setup and results interpretation.

Example 9. A system for performing plasma simulations includes a domain-specific computer architecture designed for plasma simulations, an AI-powered user interface for interacting with the domain-specific computer architecture, and a controller configured to manage simulation execution and data flow between the AI-powered user interface and the domain-specific computer architecture. In some embodiments, by using the domain-specific computer architecture optimized for a particular plasma simulation and an artificial intelligence (AI)-powered user interface to input and perform the particular plasma simulation through parallelized computer architecture, the domain-specific computer architecture can advantageously reduce the expertise barrier that prevents many process engineers from utilizing plasma simulations effectively, decrease the long simulation times of conventional plasma simulation methods, and simplify the complexity of setting up and interpreting multi-physics simulations that span many scales in time and space.

Example 10. The system of example 9, where the domain-specific computer architecture includes multiple specialized physics solvers, each with dedicated memory and arithmetic units designed for specific plasma simulation calculations, an inter-solver communication circuit for coordinating data exchange between different physics solvers, and a distributed shared memory system for parallel processing of large-scale plasma simulations.

Example 11. The system of one of examples 9 or 10, where the AI-powered user interface includes a natural language processing module for interpreting user queries and commands, a simulation setup wizard that guides non-expert users through parameter selection based on their process specifications, and a results visualization module that generates interactive, multi-dimensional representations of simulation outcomes.

Example 12. The system of one of examples 9 to 11, where the controller is further configured to dynamically allocate computational resources based on simulation complexity and urgency, monitor simulation progress and provide real-time status updates to the AI-powered user interface, and implement error detection and recovery mechanisms to ensure simulation reliability.

Example 13. The system of one of examples 9 to 12, further including a machine learning module configured to analyze historical simulation data and actual process outcomes to improve simulation accuracy over time, suggest adjusted simulation parameters based on user- defined objectives and constraints, and identify potential process improvements by comparing simulation results with ideal theoretical models.

Example 14. The system of one of examples 9 to 13, further including an integration layer that enables direct connection with semiconductor manufacturing equipment for real-time data exchange, synchronization with digital twin models of a manufacturing process, and secure data sharing with external analysis tools and databases while maintaining intellectual property protection.

Example 15. An AI-powered interface for plasma simulations includes one or more processors, and a memory storing a program and coupled to the one or more processors, the program including instructions to be executed in the one or more processors. The instructions including a plurality of modules of instructions, the plurality of modules including a natural language processing module for interpreting user queries, a simulation parameter generation module for converting user queries into simulation inputs, a results analysis module for interpreting simulation outputs, and a recommendation module for suggesting process improvements based on simulation results. In some embodiments, by using the artificial intelligence (AI) powered interface to input and perform the particular plasma simulation through parallelized computer architecture, such as a domain-specific computer architecture optimized by a trained AI model, the AI-powered interface can advantageously reduce the expertise barrier that prevents many process engineers from utilizing plasma simulations effectively, decrease the long simulation times of conventional plasma simulation methods, and simplify the complexity of setting up and interpreting multi-physics simulations that span many scales in time and space.

Example 16. The AI-powered interface of example 15, where the natural language processing module is configured to recognize and interpret domain-specific terminology related to plasma physics and semiconductor manufacturing, maintain context across multiple user interactions within a simulation session, and generate clarifying questions when user queries are ambiguous or incomplete.

Example 17. The AI-powered interface of one of examples 15 or 16, where the simulation parameter generation module includes a knowledge base of predefined simulation templates for common plasma processes, a modification algorithm that balances simulation accuracy with computational resource constraints, and a validation system that checks generated parameters against physical laws and equipment limitations.

Example 18. The AI-powered interface of one of examples 15 to 17, where the results analysis module is configured to generate multi-dimensional visualizations of plasma characteristics across spatial and temporal domains, perform statistical analysis to identify correlations between input parameters and simulation outcomes, and compare simulation results with a database of historical process data to validate accuracy.

Example 19. The AI-powered interface of one of examples 15 to 18, where the recommendation module is designed to prioritize suggested improvements based on their predicted impact on performance indicators, provide explanations for each recommendation including underlying physical principles, and simulate potential outcomes of implementing recommendations before applying them to actual processes.

Example 20. The AI-powered interface of one of examples 15 to 19, further including a learning module that continuously updates its knowledge base from user interactions, simulation outcomes, and actual process results, adapts its communication style and level of technical detail based on individual user preferences and expertise, and identifies patterns in successful simulations to refine future parameter suggestions and process recommendations.

Example 21. A method of designing domain-specific computer architecture (DSA) for plasma simulation includes providing a training set to an artificial intelligence (AI) model, the training set including plasma processing parameters and hardware parameters used for the plasma processing parameters, and training the AI model using the training set to form a trained AI model, the trained AI model configured to output hardware parameters based on a plasma process parametrization. The method further includes inputting a desired plasma process parametrization to the trained AI model, the trained AI model outputting hardware parameters, and designing, using the hardware parameters, the DSA for performing plasma simulations of the desired plasma process parametrization. In some embodiments, by performing the method of designing domain-specific computer architecture (DSA), using the trained AI model, and optimizing the DSA through multiple iterations and simulations performed by the AI model, the DSA can advantageously reduce the expertise barrier that prevents many process engineers from utilizing plasma simulations effectively, decrease the long simulation times of conventional plasma simulation methods, and simplify the complexity of setting up and interpreting multi-physics simulations that span many scales in time and space.

Example 22. The method of example 21, further including performing plasma simulation using a chip fabricated in accordance with the DSA.

Example 23. The method of one of examples 21 or 22, where the hardware parameters include at least one of memory allocation specifications, arithmetic unit configurations, and interconnect topologies.

Example 24. The method of one of examples 21 to 23, further including iteratively refining the trained AI model by performing plasma simulations using the DSA, comparing results of the plasma simulations to actual plasma processing results, and updating the training set with comparison results.

Example 25. The method of one of examples 21 to 24, where designing the DSA includes generating a hardware description language (HDL) specification based on the hardware parameters, and synthesizing the HDL specification to produce a physical design of the DSA.

Example 26. The method of one of examples 21 to 25, where the plasma processing parameters in the training set include at least one of gas flow rates, chamber pressures, RF power levels, and substrate temperatures.

Example 27. The method of one of examples 21 to 26, further including implementing mixed precision computation in the DSA by identifying portions of plasma simulation calculations that can use reduced numerical precision without significantly affecting overall simulation accuracy, and configuring the DSA to use lower precision arithmetic units for the identified portions of the plasma simulation calculations.

Example 28. A method of training an artificial intelligence (AI) model for optimally allocating resources of a domain-specific computer architecture (DSA) includes providing a training set to the AI model, the training set including plasma processing parameters and resource allocations of the DSA used for the plasma processing parameters, the DSA including specialized physics solvers with dedicated memory and arithmetic units and an inter-solver communication circuit for coordinating data exchange between the specialized physics solvers, the resource allocations including information on how the inter-solver communication circuit coordinated data exchange between the specialized physics solvers and how each dedicated memory was allocated. The method further includes training the AI model using the training set to form a trained AI model, the trained AI model configured to output resource allocation information based on the DSA and the plasma processing parameters, and inputting a DSA configuration and a set of plasma processing parameters for a desired plasma process to the trained AI model, the trained AI model outputting resource allocation information for the DSA configuration. The method further includes allocating resources in the DSA based on the resource allocation information outputted from the trained AI model, and performing a plasma simulation for the desired plasma process using the allocated resources. In some embodiments, by using the domain-specific computer architecture optimized for a particular plasma simulation and an AI-powered user interface to input and perform the particular plasma simulation through parallelized computer architecture comprising optimized resource allocation using the trained AI model, the domain-specific computer architecture can advantageously reduce the expertise barrier that prevents many process engineers from utilizing plasma simulations effectively, decrease the long simulation times of conventional plasma simulation methods, and simplify the complexity of setting up and interpreting multi-physics simulations that span many scales in time and space.

Example 29. The method of example 28, further including validating the trained AI model by inputting test plasma processing parameters to the trained AI model, receiving output resource allocations from the trained AI model, performing plasma simulations using the DSA with the output resource allocations, and comparing results of the plasma simulations to predetermined accuracy thresholds.

Example 30. The method of one of examples 28 or 29, where the specialized physics solvers include at least two of a fluid dynamics solver, an electromagnetic field solver, a particle-in-cell solver, and a chemical kinetics solver.

Example 31. The method of one of examples 28 to 30, where the resource allocations in the training set further include clock frequency settings for each of the specialized physics solvers, precision levels for arithmetic operations in each of the specialized physics solvers, and cache allocation strategies for each dedicated memory.

Example 32. The method of one of examples 28 to 31, further includes periodically updating the training set with new plasma processing parameters and corresponding resource allocations obtained from actual use of the DSA in plasma simulations, and retraining the AI model using the updated training set to improve accuracy of the resource allocation information.

Example 33. The method of one of examples 28 to 32, where training the AI model includes using a reinforcement learning algorithm to modify a reward function, the reward function based on at least one of simulation accuracy, simulation speed, and power consumption of the DSA during simulation.

Example 34. A method of training an artificial intelligence (AI) model to recommend process adjustments for a plasma process includes providing a training set to the AI model, the training set including results of a plasma simulation executed on a domain-specific computer architecture (DSA) designed for plasma physics computations, and training the AI model using the training set to form a trained AI model, the trained AI model configured to output recommendations for process adjustments to an input plasma process, the process adjustments including changes to processing parameters of the input plasma process. The method further includes adjusting processing parameters for performing a plasma process in a plasma chamber based on the process adjustments, and performing the plasma process on a substrate loaded into the plasma chamber based on adjusted processing parameters.

Example 35. The method of example 34, where the results of the plasma simulation in the training set include at least one of etch rates, deposition rates, plasma density distributions, and species concentration profiles.

Example 36. The method of one of examples 34 or 35, further including validating the trained AI model by inputting a test plasma process to the trained AI model, receiving recommended process adjustments from the trained AI model, executing a plasma simulation of the test plasma process with the recommended process adjustments on the DSA, and comparing results of the plasma simulation to predetermined performance metrics.

Example 37. The method of one of examples 34 to 36, where the processing parameters include at least two of gas flow rates, chamber pressures, RF power levels, bias voltages, and process durations.

Example 38. The method of one of examples 34 to 37, further including periodically updating the training set with new plasma simulation results obtained from actual plasma processes performed using recommendations from the trained AI model, and retraining the AI model using the updated training set to improve accuracy of the process adjustment recommendations.

Example 39. The method of one of examples 34 to 38, where training the AI model includes using a machine learning algorithm selected from a group including neural networks, decision trees, support vector machines, and Gaussian processes.

Example 40. The method of one of examples 34 to 39, further including configuring the trained AI model to output, along with recommendations for process adjustments, confidence levels associated with each recommended adjustment, and filtering recommendations based on a predetermined confidence threshold.

Example 41. A method for accelerating plasma simulations in semiconductor manufacturing includes receiving simulation parameters through an AI-powered user interface, and executing a plasma simulation on a domain-specific computer architecture designed for plasma physics computations. The method further includes analyzing simulation results using the AI-powered user interface, and providing recommendations for process adjustments based on the simulation results.

Example 42. The method of example 41, where the AI-powered user interface includes a chatbot capable of interpreting natural language inputs and guiding non-expert users through a simulation setup process.

Example 43. The method of one of examples 41 or 42, where the domain-specific computer architecture includes dedicated memory units for each physics solver, arithmetic units with dedicated memory designed for plasma physics calculations, and an inter-solver controller for synchronizing operations between different physics solvers.

Example 44. The method of one of examples 41 to 43, where executing the plasma simulations includes parallelizing computations across multiple sub-domains of a simulated plasma region using a distributed shared memory architecture.

Example 45. The method of one of examples 41 to 44, where analyzing simulation results includes generating visual representations of plasma characteristics and comparing them to predefined process targets.

Example 46. The method of one of examples 41 to 45, further including integrating the simulation results and recommendations into a digital twin model of the semiconductor manufacturing process for continuous process modification.

Example 47. The method of one of examples 41 to 46, where providing recommendations for process adjustments includes generating a ranked list of parameter modifications based on their predicted impact on process outcomes, simulating effects of each recommended adjustment using the domain-specific computer architecture, and presenting the recommendations to a user through the AI-powered user interface with explanations of expected improvements.

Example 48. The method of one of examples 41 to 47, further including integrating real-time data from semiconductor manufacturing equipment into the simulation parameters, continuously updating a plasma simulation model based on discrepancies between simulated and actual process results, and automatically initiating new simulations when process drift is detected, to proactively suggest corrective actions.

Example 49. A method for integrating plasma simulations into a semiconductor manufacturing workflow includes receiving process data from manufacturing equipment, initiating a plasma simulation based on the process data using a domain-specific computer architecture, generating process adjustments based on simulation results, and applying the process adjustments to the manufacturing equipment.

Example 50. The method of example 49, where receiving process data includes collecting real-time sensor data from the manufacturing equipment and synchronizing it with a digital twin model of the semiconductor manufacturing process.

Example 51. The method of one of examples 49 or 50, where initiating the plasma simulation includes preprocessing the process data using an AI-powered interface to adjust simulation parameters, and allocating computational resources on the domain-specific computer architecture based on complexity of the plasma simulation.

Example 52. The method of one of examples 49 to 51, where generating process adjustments includes analyzing simulation results using machine learning algorithms to identify deviations from target process outcomes, and formulating adjustment recommendations that adjust multiple process variables simultaneously.

Example 53. The method of one of examples 49 to 52, where applying the process adjustments includes automatically updating control parameters of the manufacturing equipment within predefined safety limits, and logging all adjustments in a process history database for traceability and future analysis.

Example 54. The method of one of examples 49 to 53, further including continuously monitoring impacts of applied process adjustments on product quality and yield, refining plasma simulation models based on observed outcomes, and updating an AI-powered interface to improve future simulation accuracy and adjustment recommendations.

Example 55. A memory architecture optimized for parallel computation and mixed precision storage includes storage blocks for storing data, each storage block including an exponent bin, a low precision bin, and a plurality of high precision bins, and an input/output (I/O) unit configured such that the I/O unit can rapidly multiply or add on the data in an entire block of the storage blocks during I/O operations.

Example 56. The memory architecture of example 55, where the storage blocks separately store the exponent bin, the low precision bin, and the plurality of high precision bins, and where the storage blocks are configured to retrieve and store entire blocks simultaneously.

Example 57. A packaging architecture includes domain-specific computers, a shared memory, a controller, and an input/output (I/O) module, where physical space of the packaging architecture includes separate domains, each of the separate domains assigned to one of the domain-specific computers.

Example 58. The packaging architecture of example 57, where the packaging architecture includes between 2 and 10 of the domain-specific computers allocated on a card, the card including the shared memory, the controller, and the I/O module.

Example 59. The packaging architecture of one of examples 57 or 58, where the packaging architecture includes between 2 and 20 of the card disposed in a cabinet, the cabinet including a cabinet shared memory, a cabinet I/O module, and a cabinet controller.

While the inventive aspects are described primarily in the context of plasma simulations for semiconductor manufacturing, it should also be appreciated that these inventive aspects may also apply to other computational fluid dynamics applications, multi-physics simulations in different domains, and scientific computing problems utilizing specialized hardware acceleration. In particular, aspects of this disclosure may similarly apply to simulations of combustion processes, weather modeling, molecular dynamics calculations, and other models characterized by multiple coupled physical processes operating across disparate spatial and temporal scales.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, embodiments may comprise combinations of embodiments discussed in FIGS. 1-9. It is therefore intended that the appended claims encompass any such modifications or embodiments.

What is claimed is:

1. A method of designing domain-specific computer architecture (DSA) for plasma simulation, the method comprising:
providing a training set to an artificial intelligence (AI) model, the training set comprising plasma processing parameters and hardware parameters used for the plasma processing parameters;
training the AI model using the training set to form a trained AI model, the trained AI model configured to output hardware parameters based on a plasma process parametrization;
inputting a desired plasma process parametrization to the trained AI model, the trained AI model outputting hardware parameters; and
designing, using the hardware parameters, the DSA for performing plasma simulations of the desired plasma process parametrization.

2. The method of claim 1, further comprising performing plasma simulation using a chip fabricated in accordance with the DSA.

3. The method of claim 1, wherein the hardware parameters comprise at least one of: memory allocation specifications, arithmetic unit configurations, and interconnect topologies.

4. The method of claim 1, further comprising iteratively refining the trained AI model by:
performing plasma simulations using the DSA;
comparing results of the plasma simulations to actual plasma processing results; and
updating the training set with comparison results.

5. The method of claim 1, wherein designing the DSA comprises:
generating a hardware description language (HDL) specification based on the hardware parameters; and
synthesizing the HDL specification to produce a physical design of the DSA.

6. The method of claim 1, wherein the plasma processing parameters in the training set comprise at least one of: gas flow rates, chamber pressures, RF power levels, and substrate temperatures.

7. The method of claim 1, further comprising implementing mixed precision computation in the DSA by:
identifying portions of plasma simulation calculations that can use reduced numerical precision without significantly affecting overall simulation accuracy; and
configuring the DSA to use lower precision arithmetic units for the identified portions of the plasma simulation calculations.

8. A method of training an artificial intelligence (AI) model for optimally allocating resources of a domain-specific computer architecture (DSA), the method comprising:
providing a training set to the AI model, the training set comprising plasma processing parameters and resource allocations of the DSA used for the plasma processing parameters, the DSA comprising specialized physics solvers with dedicated memory and arithmetic units and an inter-solver communication circuit for coordinating data exchange between the specialized physics solvers, the resource allocations comprising information on how the inter-solver communication circuit coordinated data exchange between the specialized physics solvers and how each dedicated memory was allocated;
training the AI model using the training set to form a trained AI model, the trained AI model configured to output resource allocation information based on the DSA and the plasma processing parameters;
inputting a DSA configuration and a set of plasma processing parameters for a desired plasma process to the trained AI model, the trained AI model outputting resource allocation information for the DSA configuration;
allocating resources in the DSA based on the resource allocation information outputted from the trained AI model; and
performing a plasma simulation for the desired plasma process using the allocated resources.

9. The method of claim 8, further comprising validating the trained AI model by:
inputting test plasma processing parameters to the trained AI model;
receiving output resource allocations from the trained AI model;
performing plasma simulations using the DSA with the output resource allocations; and comparing results of the plasma simulations to predetermined accuracy thresholds.

10. The method of claim 8, wherein the specialized physics solvers comprise at least two of: a fluid dynamics solver, an electromagnetic field solver, a particle-in-cell solver, and a chemical kinetics solver.

11. The method of claim 8, wherein the resource allocations in the training set further comprise:
clock frequency settings for each of the specialized physics solvers;
precision levels for arithmetic operations in each of the specialized physics solvers; and
cache allocation strategies for each dedicated memory.

12. The method of claim 8, further comprising:
periodically updating the training set with new plasma processing parameters and corresponding resource allocations obtained from actual use of the DSA in plasma simulations; and
retraining the AI model using the updated training set to improve accuracy of the resource allocation information.

13. The method of claim 8, wherein training the AI model comprises using a reinforcement learning algorithm to modify a reward function, the reward function based on at least one of: simulation accuracy, simulation speed, and power consumption of the DSA during simulation.

14. A method of training an artificial intelligence (AI) model to recommend process adjustments for a plasma process, the method comprising:
providing a training set to the AI model, the training set comprising results of a plasma simulation executed on a domain-specific computer architecture (DSA) designed for plasma physics computations;
training the AI model using the training set to form a trained AI model, the trained AI model configured to output recommendations for process adjustments to an input plasma process, the process adjustments comprising changes to processing parameters of the input plasma process;
adjusting processing parameters for performing a plasma process in a plasma chamber based on the process adjustments; and
performing the plasma process on a substrate loaded into the plasma chamber based on adjusted processing parameters.

15. The method of claim 14, wherein the results of the plasma simulation in the training set comprise at least one of: etch rates, deposition rates, plasma density distributions, and species concentration profiles.

16. The method of claim 14, further comprising validating the trained AI model by:
inputting a test plasma process to the trained AI model;
receiving recommended process adjustments from the trained AI model;
executing a plasma simulation of the test plasma process with the recommended process adjustments on the DSA; and
comparing results of the plasma simulation to predetermined performance metrics.

17. The method of claim 14, wherein the processing parameters comprise at least two of: gas flow rates, chamber pressures, RF power levels, bias voltages, and process durations.

18. The method of claim 14, further comprising:
periodically updating the training set with new plasma simulation results obtained from actual plasma processes performed using recommendations from the trained AI model; and
retraining the AI model using the updated training set to improve accuracy of the process adjustment recommendations.

19. The method of claim 14, wherein training the AI model comprises using a machine learning algorithm selected from a group comprising neural networks, decision trees, support vector machines, and Gaussian processes.

20. The method of claim 14, further comprising:
configuring the trained AI model to output, along with recommendations for process adjustments, confidence levels associated with each recommended adjustment; and
filtering recommendations based on a predetermined confidence threshold.
